(19) United States
(12) Patent Application Publication
(10) Pub. No.: US 2013/0187222 A1
(43) Pub. Date: Jul. 25, 2013

(54) SEMICONDUCTOR DEVICE AND METHOD OF MANUFACTURING THE SAME

(71) Applicant: Dae Jin PARK, Gyeonggi-do (KR)

(72) Inventor: Dae Jin PARK, Gyeonggi-do (KR)

(21) Appl. No.: 13/603,387

(22) Filed: Sep. 4, 2012

(30) Foreign Application Priority Data
Jan. 19, 2012 (KR) 10-2012-0006231

(51) Int. Cl. H01L 29/78; H01L 21/768

(52) U.S. Cl. 257/329; 438/672; 257/E29.262; 257/E21.585

(57) ABSTRACT

A method of manufacturing a semiconductor device includes forming a target etch layer, forming a first mask pattern on the target etch layer, wherein the first mask pattern includes line patterns extended in parallel in a first direction, forming a second mask pattern configured to include openings at positions where the openings overlap with spaces between the line patterns, before or after forming the first mask pattern, wherein each of the openings has a hole form and a first interval between the adjacent openings in the first direction is shorter than a second interval between the adjacent openings in a second direction that crosses the first direction, and forming holes by etching the target etch layer using the first mask pattern and the second mask pattern as a barrier.

### CROSS-REFERENCE TO RELATED APPLICATION

Priority to Korean patent application number 10-2012-0006231 filed on Jan. 19, 2012, the entire disclosure of which is incorporated by reference herein, is claimed.

### BACKGROUND

Embodiments of this disclosure relate to semiconductor devices and method of manufacturing the same and, more particularly, to semiconductor devices including holes and method of manufacturing the same.

When fabricating semiconductor devices, a photolithography process is used to form desired patterns. In the photolithography process, a photoresist layer is formed by coating a photoresist, i.e., a kind of chemicals that respond to light. Photoresist patterns having a desired form are formed by exposing and developing the photoresist layer. The photoresist is divided into a positive type and a negative type depending on the characteristics of materials.

In the photoresist of the positive type, parts exposed to light are removed by a developer, thus forming patterns. If the photoresist of the positive type is used, there are concerns in that a process margin may be high, but the degree of development may be low.

In contrast, in the photoresist of the negative type, parts exposed to light are cured. Thus, the exposed parts remains. However, parts not exposed to light are removed. Thus, photoresist patterns are formed. If the photoresist of the negative type is used, there are concerns in that the degree of development may be high, but a process margin may be low.

As the integration degree of semiconductor devices is recently increased, some difficulties in forming patterns having a desired form may occur because of using a photolithography process. In particular, when forming a plurality of contact holes, such as source contact holes, drain contact holes, and the channel holes of a 3-D nonvolatile memory device at the same time, a photolithography process may have some limitation to form holes having desired shape and size at desired positions.

### BRIEF SUMMARY

An exemplary embodiment of this disclosure provides a method of manufacturing a semiconductor device, which is capable of forming holes having a desired form, and a semiconductor device formed by the method.

In an aspect of this disclosure, a method of manufacturing a semiconductor device includes forming a target etch layer, forming a first mask pattern on the target etch layer, wherein the first mask pattern includes line patterns extended in parallel in a first direction, forming a second mask pattern configured to include openings at positions where the openings overlap with spaces between the line patterns, before or after forming the first mask pattern, wherein each of the openings has ahole form and a first interval between the adjacent openings in the first direction is shorter than a second interval between the adjacent openings in a second direction that crosses the first direction, and forming holes by etching the target etch layer using the first mask pattern and the second mask pattern as a barrier.

In another aspect of this disclosure, a semiconductor device includes vertical pillars arranged in a matrix of a first direction and a second direction that crosses the first direction, wherein a first interval between the adjacent vertical pillars in the first direction is shorter than a second interval between the adjacent vertical pillars in the second direction, and interlayer insulating layers and conductive layers stacked alternately and configured to surround the vertical pillars. Each vertical pillar has a polygonal section at least one surface of which is a curved surface.

### BRIEF DESCRIPTION OF THE DRAWINGS

FIG. 1 is a layout diagram of a semiconductor device according to an embodiment of this disclosure;

FIGS. 2A to 2C show first and second mask patterns according to a first embodiment of this disclosure;

FIGS. 3A to 3C show first and second mask patterns according to a second embodiment of this disclosure;

FIGS. 4A to 7B are diagrams illustrating a method of manufacturing a semiconductor device according to a third embodiment of this disclosure;

FIGS. 8A and 8B show the structures of a 3-D nonvolatile memory device according to a fourth embodiment of this disclosure;

FIGS. 9A and 9B show the structures of a 3-D nonvolatile memory device according to a fifth embodiment of this disclosure;

FIGS. 10A to 10C show the structures of a 3-D nonvolatile memory device according to a sixth embodiment of this disclosure;

FIG. 11 shows the construction of a memory system according to an embodiment of this disclosure; and

FIG. 12 shows the construction of a computing system in accordance with an embodiment of this disclosure.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

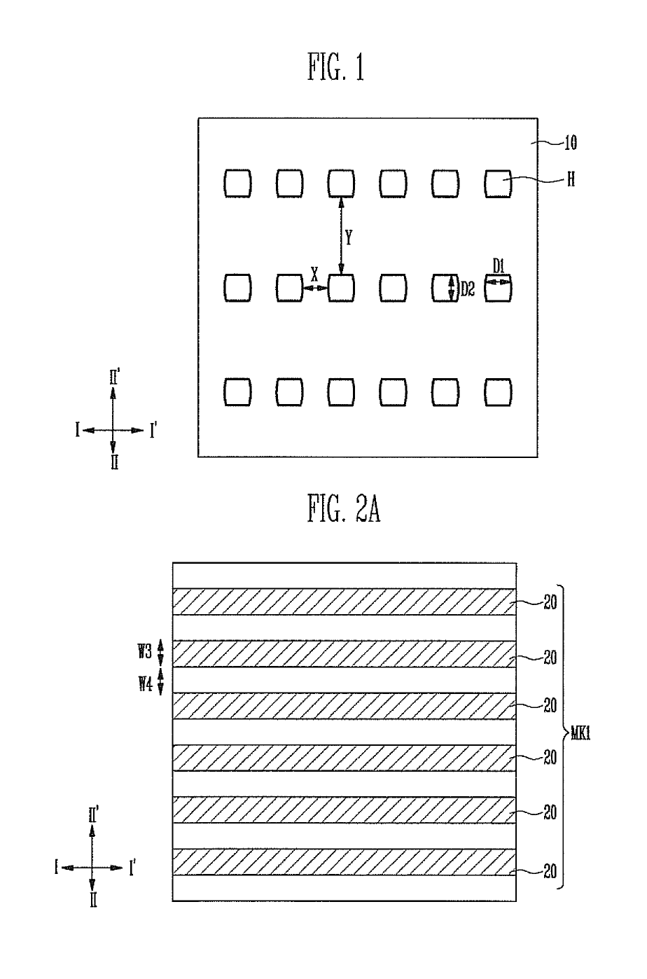

FIG. 1 is a layout diagram of a semiconductor device according to an embodiment of this disclosure.

As shown in FIG. 1, the semiconductor device includes a plurality of holes H formed by etching material layers 10. For example, the holes H may include source contact holes coupled to source regions, drain contact holes coupled to drain regions, the channel holes of a 3-D nonvolatile memory device, and the electrode holes of a 3-D nonvolatile memory device.

Each of the holes H may have a variety of sections, such as a quadrangle and a circle. A first width D1 of the holes H in a first direction I-I′ may be substantially same as a second width D2 thereof in a second direction II-II′. That is, the first width D1 and the second width D2 substantially have the same value by taking errors due to a limit in the process into consideration. In particular, the hole H may be formed to have a polygonal section having at least one curved surface. For example, the hole H is formed to have a section of a quadrangle, but at least one surface of the quadrangle may be a curved surface. FIG. 1 shows the case each of the top surface and the bottom surface of the hole H has a flat surface and each of the left surface and the right surface thereof has a curved surface.

Intervals X between the holes H adjacent to each other in the first direction I-I′ are different from intervals Y between the holes H adjacent to each other in the second direction II-II′. The interval Y in the second direction II-II′ may have a greater value than the interval X in the first direction I-I′. In particular, a ratio of the interval X and the interval Y may be 1:3 or higher.

In order to form the holes having the above-described layout, a photolithography process using a mask pattern having openings at holes' positions should be performed. However, because of a technical limit in the photolithography process, if the interval X in the first direction I-I′ is different from the interval Y in the second direction II-II′, the width of each opening in the first direction I-I′ may be different from the width of each opening in the second direction II-II′. The different intervals may cause different widths of each opening for holes, which are designed to have same widths of I-I′ and II-II′ directions.

In according to embodiments of this disclosure, two mask patterns are stacked and used as one mask pattern in order to form a mask pattern including openings arranged so that the width of the opening in the first direction I-I′ is substantially the same as the width of the opening in the second direction II-II′. In particular, a first mask pattern having openings of line/space forms and a second mask pattern having openings of a hole form are used in order to correct a shape of the openings of the second mask pattern using the first mask pattern.

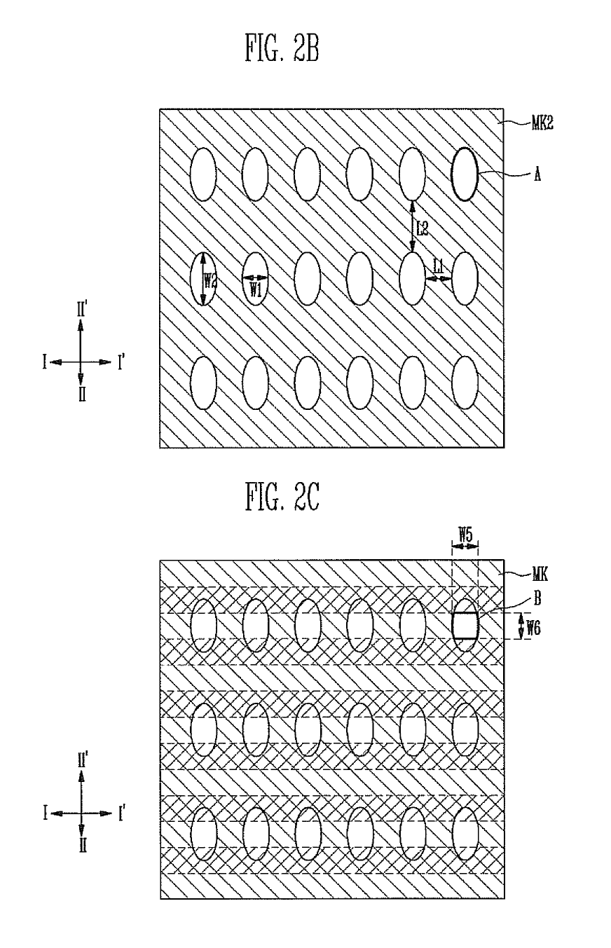

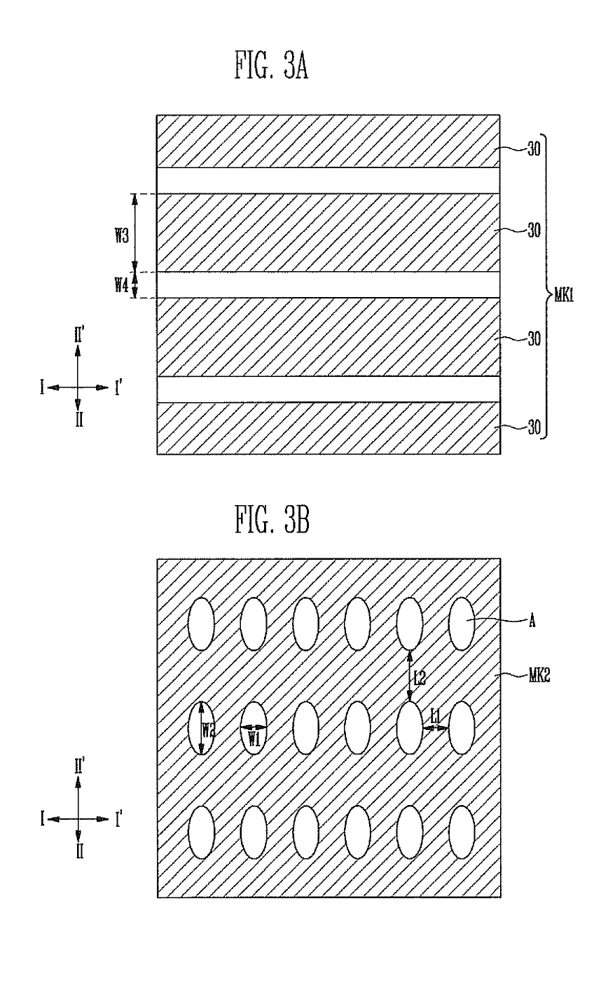

FIGS. 2A and 2B show first and second mask patterns according to a first embodiment of this disclosure. FIG. 2C shows a final mask pattern formed by stacking the first and the second mask patterns.

As shown in FIG. 2A, a first mask pattern MK1 includes line patterns 20 extended in parallel in a first direction I-I′. The width W3 of each of the line patterns 20 and a space width W4 between the line patterns 20 may have the same value (W3=W4).

As shown in FIG. 2B, a second mask pattern MK2 includes a plurality of openings ‘A’ each having a hole form. The openings ‘A’ are arranged in a matrix of the first direction I-I′ and a second direction II-II′. The openings ‘A’ are located at positions overlapping with the spaces of the first mask pattern MK1.

Each of the openings A may have an oval or a rectangle so that a second width W2 in the second direction II-II′ is greater than a first width W1 in the first direction I-I′ (W1<W2). Furthermore, a first distance L1 between two adjacent openings ‘A’ in the first direction I-I′ may be smaller than a second distance L2 between two other adjacent openings ‘A’ in the second direction II-II′ (L1<L2).

Furthermore, the first width W1, the space width W3, and the space width W4 may have the same value (W1=W3=W4<W2). In this case, the openings ‘A’ of the second mask pattern MK2 are placed at positions overlapping with the even-numbered or odd-numbered spaces of the first mask pattern MK1. The odd-numbered or even-numbered spaces are covered with the second mask pattern MK2.

As shown in FIG. 2C, a final mask pattern MK is formed by stacking the first and the second mask patterns MK1 and MK2. The final mask pattern MK includes openings ‘B’ at regions where the spaces of the first mask pattern MK1 overlap with the openings ‘A’ of the second mask pattern MK2.

Each opening ‘A’ in the second mask pattern MK2 is placed at the center of each space. Since the space width W4 between the line patterns 20 is smaller than the second width W2 of each opening ‘A’ in the second mask pattern MK2, the second width W2 of the opening ‘A’ can be reduced through the first mask pattern MK1. As a result, the final mask pattern MK includes the openings ‘B’ located at places where an interval between the openings B in the first direction I-I′ is different from an interval between the openings B in the second direction II-II′ and a width W5 of the opening B in the first direction I-I′ is the same as a width W6 of the opening B in the second direction II-II′.

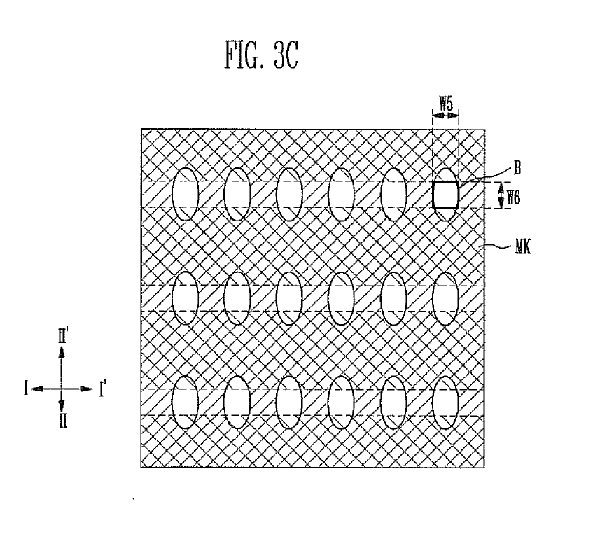

FIGS. 3A and 3B show first and second mask patterns according to a second embodiment of this disclosure. FIG. 3C shows a final mask pattern formed by stacking the first and the second mask patterns.

As shown in FIG. 3A, a first mask pattern MK1 includes line patterns 30 extended in parallel in a first direction I-I′. The width W3 of each of the line patterns 30 may be greater than a space width W4 between the line patterns 30 (W3>W4).

As shown in FIG. 3B, a second mask pattern MK2 includes a plurality of openings ‘A’ each having a hole form. The openings ‘A’ are arranged in a matrix of the first direction I-I′ and a second direction II-II′. The openings ‘A’ are located at positions overlapping with the spaces of the first mask pattern MK1.

Each of the openings ‘A’ may have an oval or a rectangle. A second width W2 in the second direction II-II′ is greater than a first width W1 in the first direction I-I′ (W1<W2). Furthermore, a first distance L1 between two adjacent openings ‘A’ in the first direction I-I′ may be smaller than a second distance L2 between two adjacent openings ‘A’ in the second direction II-II′ (L1<L2).

Furthermore, the first width W1 and the space width W4 may have the same value (W1=W4<W2). The width W3 of the line pattern 30 may be greater than the second distance L2 (L2<W3). In this case, the openings ‘A’ of the second mask pattern MK2 are placed in the respective spaces of the first mask pattern MK1.

As shown in FIG. 3C, a final mask pattern MK is formed by stacking the first and the second mask patterns MK1 and MK2. The final mask pattern MK includes openings B at regions where the spaces of the first mask pattern MK1 overlap with the openings ‘A’ of the second mask pattern MK2. As a result, the final mask pattern MK includes the openings ‘B’ at places where an interval between the openings ‘B’ in the first direction I-I′ is different from an interval between the openings ‘B’ in the second direction II-II′ and a width W5 of the opening ‘B’ in the first direction is the same as a width W6 of the opening B in the second direction II-II′.

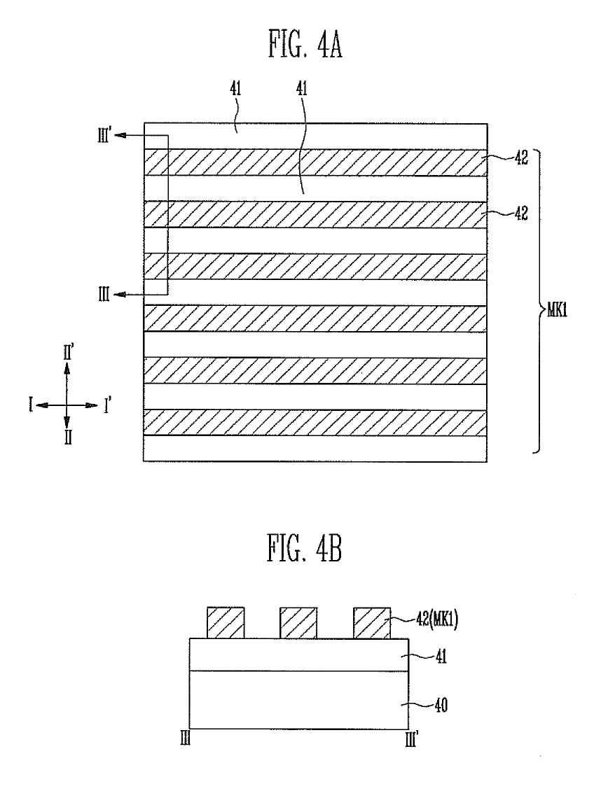

FIGS. 4A to 7B are diagrams illustrating a method of manufacturing a semiconductor device according to a third embodiment of this disclosure. Figures ‘A’ in each pair of figures are plan views, while figures ‘B’ in the figures are cross-sectional views taken along lines III-III′ in the figures ‘A’. In the embodiment, holes may be formed using the mask patterns according to the first embodiment.

As shown in FIGS. 4A and 4B, a target layer 41 is formed on a substrate 40 in which necessary underlying structures are formed.

If the method is for forming holes which serve as source contact holes coupled to source regions, drain contact holes coupled to drain regions, or the like, the target layer 41 may be formed of an insulating layer.

If the method is for forming holes which serves as the channel holes or the electrode holes in a 3-D nonvolatile memory device, the target layer 41 may include first material layers and second material layers which are alternately stacked. The first material layer may be used to form word lines, a source select line, or a drain select line. The second material layer may be used to form an interlayer insulating layer. Herein, the first material layer and the second material layer are made of materials having different etch selectivity. For example, the first material layer may be formed of a conductive layer, while the second material layer may be formed of an interlayer insulating layer. Otherwise, the first and second material layers may include different sacrificial layers.

In an embodiment, the first material layer may be formed of a conductive layer such as a polysilicon layer, while the second material layer may be formed of an insulating layer such as an oxide layer. In another embodiment, the first material layer may be formed of a conductive layer such as a doped polysilicon layer or a doped amorphous silicon layer, while the second material layer may be formed of a sacrificial layer such as an undoped polysilicon layer or an undoped amorphous silicon layer. In yet another embodiment, the first material layer may be formed of a sacrificial layer such as a nitride layer, while the second material layer may be formed of an insulating layer such as an oxide layer.

A first mask pattern MK1 is formed on the target layer 41. The first mask pattern MK1 includes line patterns 42 extended in parallel in the first direction I-I′ (refer to FIG. 2 or 3).

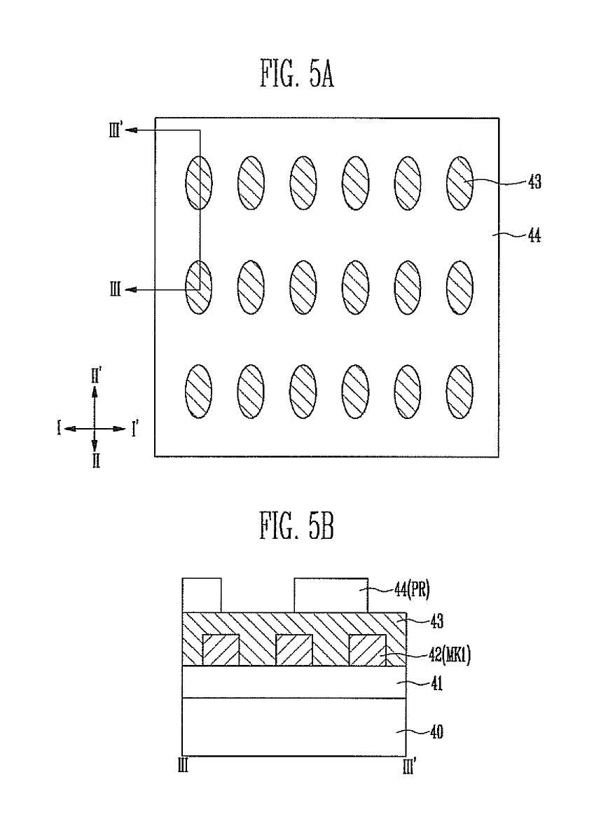

As shown in FIGS. 5A and 5B, a hard mask layer 43 for a second mask pattern is formed on the first mask pattern MK1. The hard mask layer 43 is formed to a sufficient thickness to fill the spaces between the line patterns 42 of the first mask pattern MK1 and cover the top of the line patterns 42.

A photoresist layer is formed on the hard mask layer 43. Exposure and development processes on the photoresist layer form photoresist patterns (PR) 44. The photoresist layer may be a photoresist layer of a positive type. In that case, the exposed regions are removed in the development process. Thus, the photoresist patterns have the same shape as a second mask pattern.

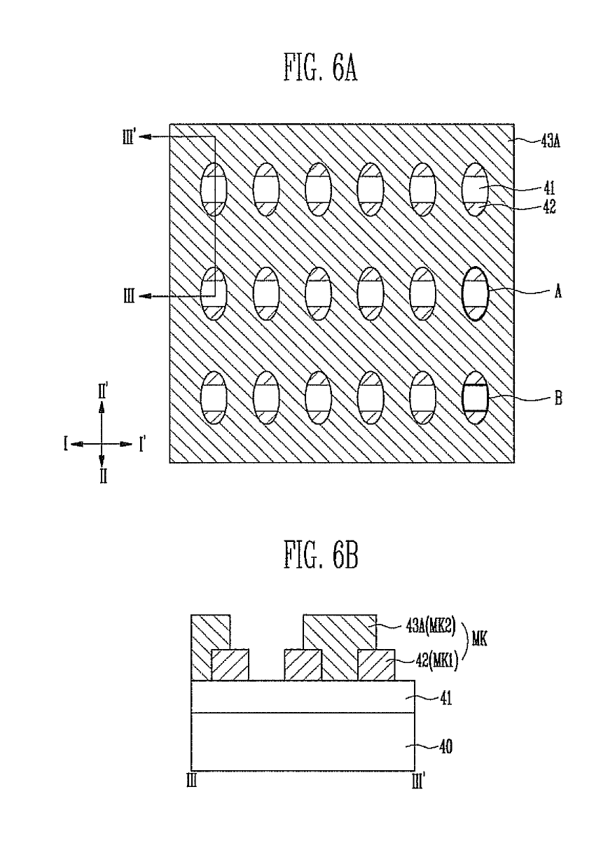

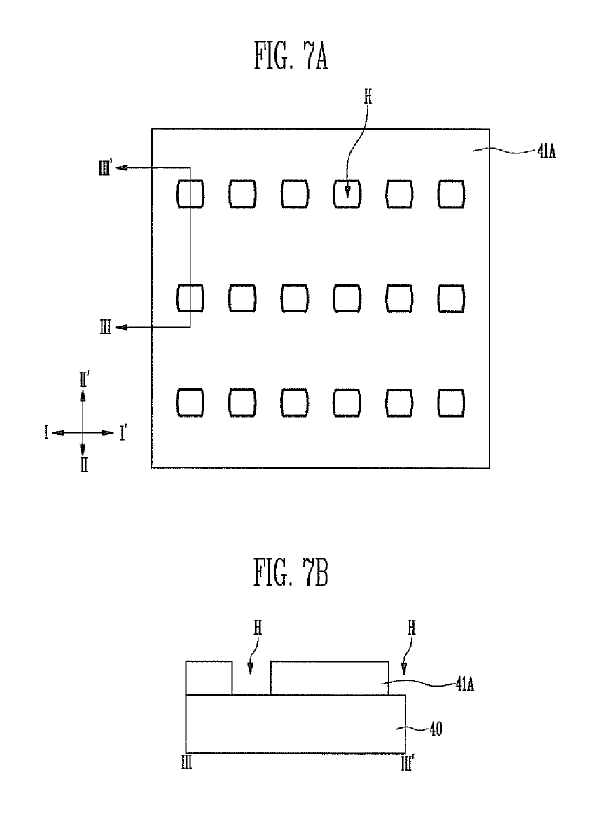

As shown in FIGS. 6A and 6B, a second mask pattern (MK2) 43A is formed by etching the hard mask layer 43 using the photoresist patterns (PR) 44 as a barrier.

The second mask pattern (MK2) 43A includes openings ‘A’ each having a hole form ‘A’. The openings ‘A’ are formed to fill the spaces between the line patterns 42. The openings ‘A’ are arranged at positions overlapping with the spaces between the line patterns 42 in the first mask pattern MK1. Here, a first interval between two adjacent openings ‘A’ in the first direction I-I′ is shorter than a second interval between other two adjacent openings A in the second direction II-II′. Furthermore, in each opening ‘A’, a second width in the second direction II-II′ is greater than a first width in the first direction I-I′.

The spaces between the line patterns 42 of the first mask pattern Mk1 are alternately exposed through the openings ‘A’ of the second mask pattern (MK2) 43A. For example, the odd-numbered spaces may be exposed through the openings ‘A’ while the even-numbered spaces may be covered with the openings ‘A’. Otherwise, the odd-numbered spaces may be covered with the openings ‘A’, while the even-numbered spaces may be exposed through the openings ‘A’.

Furthermore, since the second width of the opening ‘A’ is greater than a width between the spaces, part of the line pattern 42 on the upper and lower sides of the space is exposed through the opening ‘A’.

As a result, a final mask pattern MK in which the first mask pattern MK1 and the second mask pattern (MK2) 43A are stacked is formed. The final mask pattern MK includes openings ‘B’ located at positions where an interval between two adjacent openings ‘B’ in the first direction I-I′ is shorter than an interval between two other adjacent openings ‘B’ in the second direction II-II′. In each opening ‘B’, a width in the first direction I-I′ is identical with a width in the second direction II-II′.

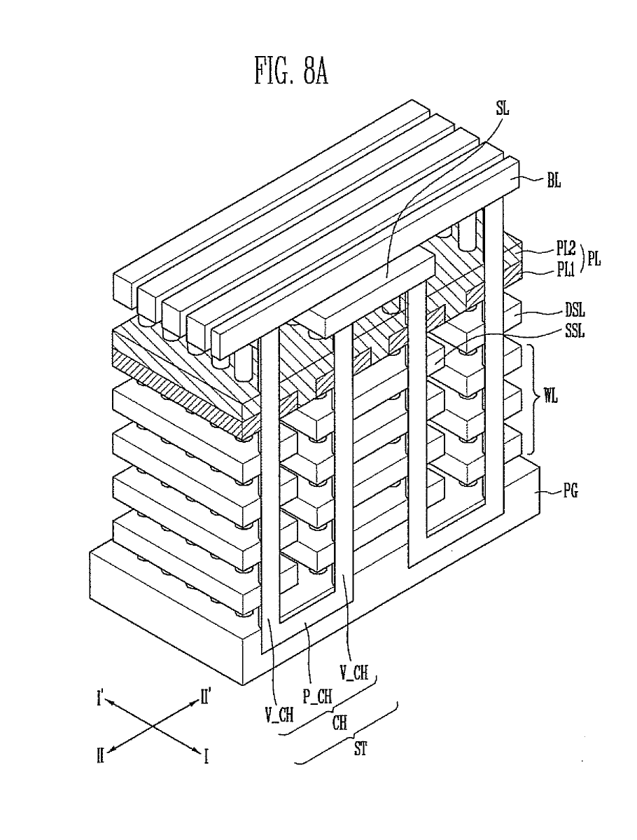

As shown in FIGS. 7A and 7B, holes H are formed by etching the target layer using the final mask pattern MK as a barrier. In the figures, the etched target layer is indicated by 41A.

As a result, an interval between two adjacent holes H in the first direction I-I′ is shorter than an interval between two other adjacent holes H in the second direction II-II′. The hole H has a width in the first direction I-I′, which is substantially identical with the width in the second direction II-II′.

Although not shown, vertical pillars are formed in the holes H. In an embodiment, if the holes H are source contact holes or drain contact holes, the vertical pillars are formed by filling the holes H with a conductive layer. The vertical pillars including a conductive material may be used as contact plugs. In another embodiment, if the holes H are electrode holes, the holes H are filled with a conductive layer so that the vertical pillars are used as vertical electrode layers.

In yet another embodiment, if the holes H are channel holes, a memory layer is formed on the insides of the holes H. Then, a vertical channel layer is formed on the memory layer. The memory layer includes a charge blocking layer, a charge trap layer, and a tunnel insulating layer. A slit is formed between the holes H by etching first material layers and second material layers. The slits are filled with an insulating layer. An additional process may be performed depending on materials that form the first material layers and the second material layers, before filling the insulating layer.

In an embodiment, if the first material layer is formed of a conductive layer and the second material layer is formed of an insulating layer, the first material layers exposed to the slits are silicided and an insulating layer (not shown) is then filled. Accordingly, a process of manufacturing memory cells is completed.

In another embodiment, if the first material layer is formed of a conductive layer and the second material layer is formed of a sacrificial layer, the second material layers exposed to the slits are removed. The slits and the regions where the second material layers have been removed are filled with an insulating layer. Accordingly, a process of manufacturing memory cells is completed.

In yet another embodiment, if the first material layer is formed of a sacrificial layer and the second material layer is formed of an insulating layer, the first material layers exposed to the slits are removed. Word lines or drain select lines/source select lines are formed by filling the regions where the first material layers have been removed with a conductive layer. Before filling the conductive layer, a charge blocking layer may be further formed on the entire surface of the regions where the first material layers have been removed. The additionally formed charge blocking layer may be an aluminum oxide (Al₂O₃) layer. Next, the slits are filled with an insulating layer. Accordingly, a process of manufacturing memory cells is completed.

Although the holes H in the embodiment are formed using the mask patterns according to the first embodiment, the holes H may be formed using the mask patterns according to the second embodiment. In other embodiments, the first mask pattern MK1 may be formed after forming the second mask pattern MK2.

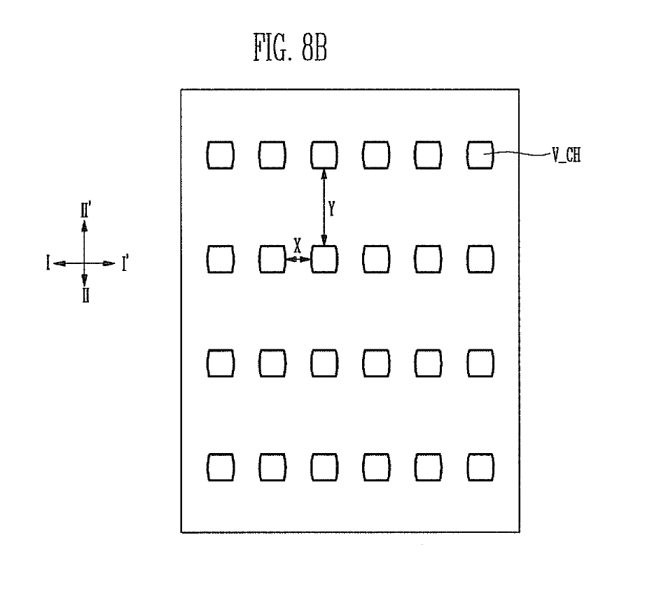

FIGS. 8A and 8B show the structures of a 3-D nonvolatile memory device according to a fourth embodiment of this disclosure. FIG. 8A is a perspective view of the 3-D nonvolatile memory device. FIG. 8B is a layout diagram of vertical channel layers.

As shown in FIGS. 8A and 8B, the 3-D nonvolatile memory device according to the fourth embodiment includes vertical pillars, each having a section of a quadrangle at least one surface of which is a curved surface. The vertical pillars are used as vertical channel layers V_CH. In particular, the top surface and the bottom surface of each of the vertical channel layers V_CH may be flat surfaces, and the left surface and the right surface thereof may be curved surface.

The 3-D nonvolatile memory device further includes pipe channels P_CH formed in a pipe gate PG. Each of the pipe channels P_CH is coupled to at least one pair of the vertical channel layers V_CH. A U-shape channel in which the pipe channel P_CH is coupled to the pair of vertical channel layers V_CH forms one string. A slit for separating source-side word lines WL and drain-side word lines WL from each other is disposed between the pair of vertical channel layers V_CH. Accordingly, an interval Y between the vertical channel layers V_CH in the first direction I-I′ is greater than an interval Y between the vertical channel layers V_CH in the second direction II-II′.

The 3-D nonvolatile memory device further includes word lines WL stacked over the pipe gate PG and configured to surround the vertical channel layers V_CH. Furthermore, source select lines SSL and drain select lines DSL of at least one layer are stacked over the word lines WL. In this structure, memory cells coupled in series between a drain select transistor and a source select transistor form one string ST. A plurality of the strings ST each having a U-shape is arranged.

The 3-D nonvolatile memory device further includes source lines SL, which are formed over the source select lines SSL and coupled to the source-side vertical channel layers V_CH, and bit lines BL which are formed over the source lines SL and coupled to the drain-side vertical channel layers V_CH.

The 3-D nonvolatile memory device further includes a pattern layer PL disposed between the source line SL and the source select lines SSL and between the bit line BL and the drain select lines DSL. The pattern layer PL may be a mask pattern MK that is used as an etch barrier when forming channel holes for forming the vertical channels V_CH. For example, after forming the vertical channel layers V_CH, both a first mask pattern MK1 and a second mask pattern MK2 may remain or a mask pattern formed on the upper side may be removed and only a mask pattern formed on the lower side may remain.

FIGS. 8A and 8B show that the pattern layer PL includes line patterns extended in parallel in the first direction I-I′, a first pattern layer PL1 configured to have the vertical channel layers V_CH penetrate therethrough in the spaces between the line patterns, and a second pattern layer PL2 configured to include openings which are formed on the first pattern layer PL1 and configured to fill the spaces between the line patterns, wherein a first interval between the adjacent openings in the first direction I-I′ is shorter than a second interval between the adjacent openings in the second direction II-II′.

The pattern layer PL may have a variety of forms.

In an embodiment, the pattern layer PL may be a first pattern layer PL1 configured to include line patterns extended in parallel in the first direction I-I′ and to have the vertical channel layers V_CH penetrate therethrough in the spaces between the line patterns.

In another embodiment, the pattern layer PL may be a second pattern layer PL2 including openings located at positions where a first interval between the adjacent openings in the first direction I-I′ is shorter than a second interval between the adjacent openings in the second direction II-II′.

In yet another embodiment, the pattern layer PL may include a first pattern layer PL1 and a second pattern layer PL2. The first pattern layer PL1 is configured to include line patterns extended in parallel in the first direction I-I′. The vertical channel layers V_CH may penetrate through the first pattern layer PL1 in the spaces between the line patterns. The second pattern layer PL2 is formed under the first pattern layer PL1. The second pattern layer PL2 is configured to include openings located at places where a first interval between the adjacent openings in the first direction I-I′ is shorter than a second interval between the adjacent openings in the second direction II-II′.

For reference, FIGS. 8A and 8B show that the word lines WL, the drain select lines DSL, and the source select lines SSL are formed at the same time using the first material layers. In other embodiments, after forming the word lines WL and the vertical channel layers V_CH, the drain select lines DSL and the source select lines SSL may be formed by an additional process. In this case, the pattern layer PL may be provided between the word lines WL and the drain select lines DSL and between the word lines WL and the source select lines SSL.

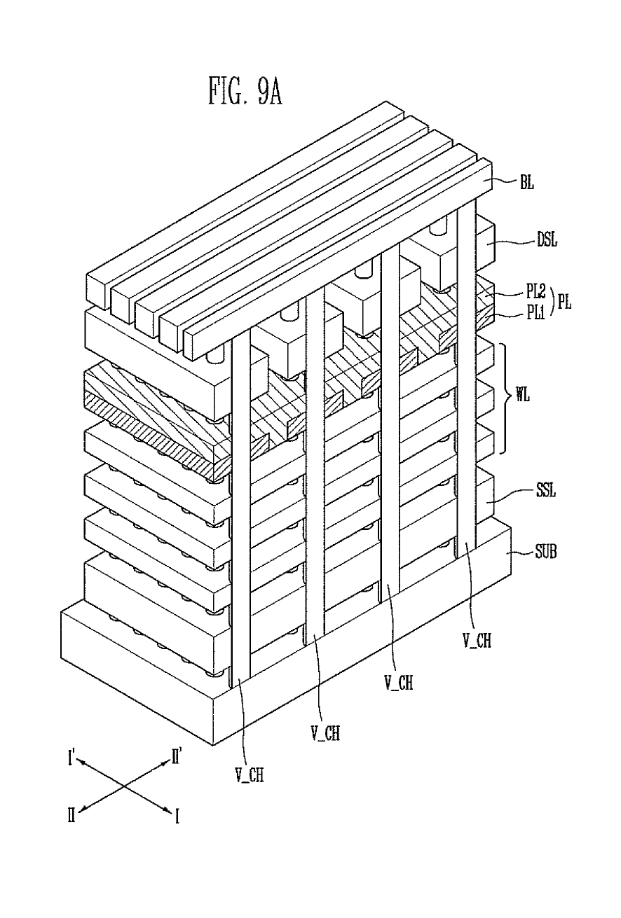

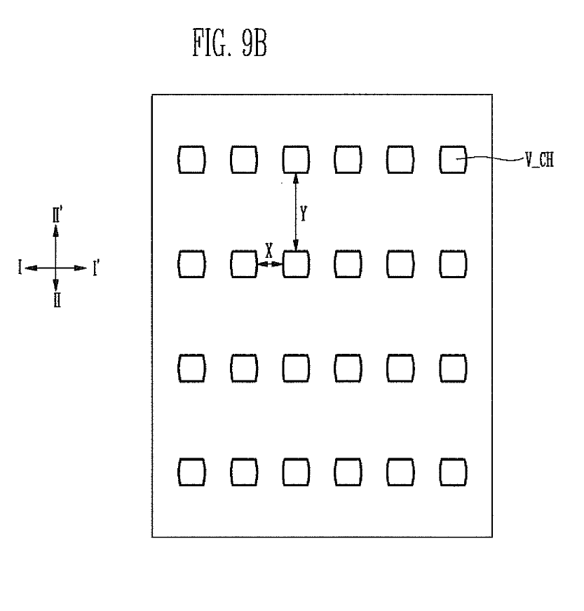

FIGS. 9A and 9B show the structures of a 3-D nonvolatile 3-D nonvolatile memory device according to a fifth embodiment of this disclosure. FIG. 9A is a perspective view of the 3-D nonvolatile memory device. FIG. 9B is a layout diagram of vertical channel layers.

As shown in FIGS. 9A and 9B, the 3-D nonvolatile memory device according to the fifth embodiment includes vertical pillars protruded from a substrate SUB including source regions (not shown). The vertical pillars are used as vertical channel layers V_CH. Each of the vertical channel layers V_CH has a rectangle pillar form. At least one surface of the rectangle pillar form may be a curved surface. Furthermore, an interval Y between the vertical channel layers V_CH in a second direction II-II′ may be greater than an interval X between the vertical channel layers V_CH in a first direction I-I′.

The 3-D nonvolatile memory device further includes one or more source select lines SSL, plural word lines WL, and one or more drain select lines DSL which are sequentially stacked over the substrate SUB and configured to surround the vertical channel layers V_CH. In this structure, memory cells coupled in series between a drain select transistor and a source select transistor form one string ST. A plurality of the strings ST is formed vertically from the substrate SUB.

The 3-D nonvolatile memory device further includes bit lines BL formed over the drain select lines DSL and coupled to the vertical channel layers V_CH.

The 3-D nonvolatile memory device further includes a pattern layer PL disposed between the word lines WL and the drain select lines DSL. The pattern layer PL may be a mask pattern MK that is used as an etch barrier when forming channel holes for forming the vertical channels V_CH. The pattern layer PL may have a variety of forms, such as those described with reference to FIGS. 8A and 8B.

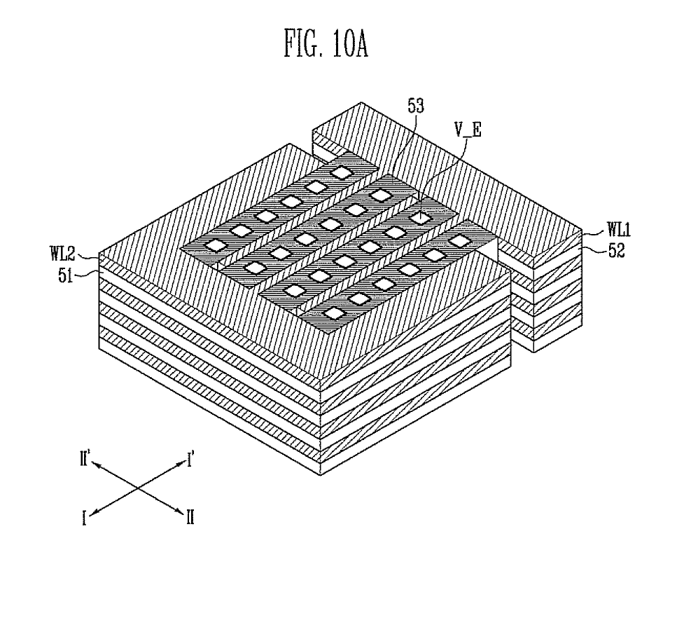

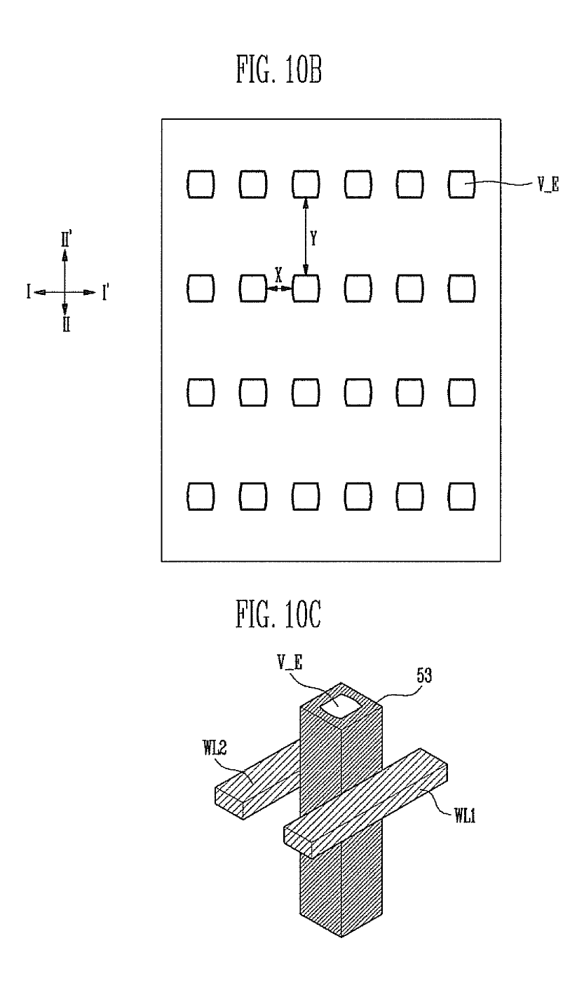

FIGS. 10A to 10C show the structures of a 3-D nonvolatile memory device according to a sixth embodiment of this disclosure. FIG. 10A is a perspective view of the 3-D nonvolatile memory device. FIG. 10B is a layout diagram of vertical electrode layers. FIG. 10C is a perspective view showing the unit cell of the 3-D nonvolatile memory device.

As shown in FIGS. 10A and 10B, the 3-D nonvolatile memory device according to the sixth embodiment includes vertical pillars, each having a polygonal section having at least one surface which is curved. The vertical pillars are used as vertical electrode layers V_E. For example, each of the vertical electrode layers V_E may have a rectangle pillar form including first to fourth surfaces. The first surface and the third surface that face each other may be a flat surface, while the second surface and the fourth surface that face each other may be a curved surface.

The 3-D nonvolatile memory device further includes first word lines WL1 and first interlayer insulating layers 52 alternately stacked and second word lines WL2 and second interlayer insulating layers 52 alternately stacked. The first word lines WL1 and the second word lines WL2 are formed in a finger type. The first word lines WL1 and the second word lines WL2 include first line patterns extended in a first direction I-I′ and second line patterns extended in a second direction II-II′. The second line patterns is configured to couple the first line patterns. Furthermore, the first line patterns of each of the first word lines WL1 and the first line patterns of each of the second word line WL2 are alternately arranged. Furthermore, the vertical electrode layers V_E are placed between the first line patterns of the first word line WL1 and the first line patterns of the second word line WL2 which are alternately arranged.

The 3-D nonvolatile memory device further includes a memory layer 53 that surround the vertical electrode layers V_E. The memory layer 53 may be made of a variable resistance material. For example, the variable resistance material may include perovskite-based materials, chalcogenide-based materials, transition metal oxides with a oxygen deficiency, or metal sulphide. SrTiO (STO) or PrCaMnO (PCMO) may be used as the perovskite-based materials. GeSbTe (GST), GeSe, CuS, or AgGe may be used as the chalcogenide-based materials. NiO, TiO₂, HfO, Nb₂O₅, ZnO, ZrO₂, WO₃, CoO, or MnO₂ may be used as the transition metal oxides. Furthermore, Cu₂S, CdS, or ZnS may be used as the metal sulphide.

FIGS. 10A to 10C show an example in which the memory layer 53 surrounds the vertical electrode layers V_E, arranged in the first direction I-I′, in a line form. In other embodiments, a plurality of memory layers 53 may surround the respective vertical electrode layers V_E. In this case, after forming the memory layer 53 in electrode holes, the vertical electrode layers V_E are formed in the electrode holes where the memory layer 53 have been formed.

As shown in FIG. 10C, the unit cell includes the vertical electrode layer V_E and the memory layer 53. The vertical electrode layer V_E is placed between the first and the second word lines WL1 and WL2 horizontally extended. The memory layer 53 is configured to surround the vertical electrode layer V_E. Accordingly, resistance of the memory layer 53 between the vertical electrode layer V_E and the first and the second word lines WL1 and WL2 is varied, thereby storing data.

Although not shown, the 3-D nonvolatile memory device may further include a pattern layer PL formed over the first word lines WL1 and the second word lines WL2, which are stacked. The pad layer PL may have a variety of forms, such as those described with reference to FIGS. 8A and 8B.

FIG. 11 shows the construction of a memory system according to an embodiment of this disclosure.

As shown in FIG. 11, the memory system 100 according to the embodiment includes a non-volatile memory device 120 and a memory controller 110.

The nonvolatile memory device 120 is configured to include a cell array including the holes described with reference to FIGS. 1 to 10B. In other embodiments, the non-volatile memory device 120 may be a multi-chip package including a plurality of flash memory chips.

The memory controller 110 is configured to control the nonvolatile memory device 120. The memory controller 110 may include SRAM 111, a central processing unit (CPU) 112, a host interface (I/F) 113, an error correction code (ECC) circuit 114, and a memory interface (I/F) 115. The SRAM 111 is used as the operating memory of the CPU 112. The CPU 112 performs an overall control operation for the data exchange of the memory controller 110. The host I/F 113 is equipped with the data exchange protocol of a host that accesses the memory system 100. Furthermore, the ECC circuit 114 circuit detects and corrects errors included in data read from the nonvolatile memory device 120. The memory I/F 115 performs an interface with the nonvolatile memory device 120. The memory controller 110 may further include RCM for storing code data for an interface with the host.

The memory system 100 configured as described above may be a memory card or a solid state disk (SSD) having combined characteristics of the nonvolatile memory device 120 and the controller 110. For example, if the memory system 100 is an SSD, the memory controller 110 may communicate with the outside (for example, a host) through one of various interface protocols, such as a USB, a MMC, a PCI-E, a SATA, a PATA, a SCSI, an ESDI, and an IDE.

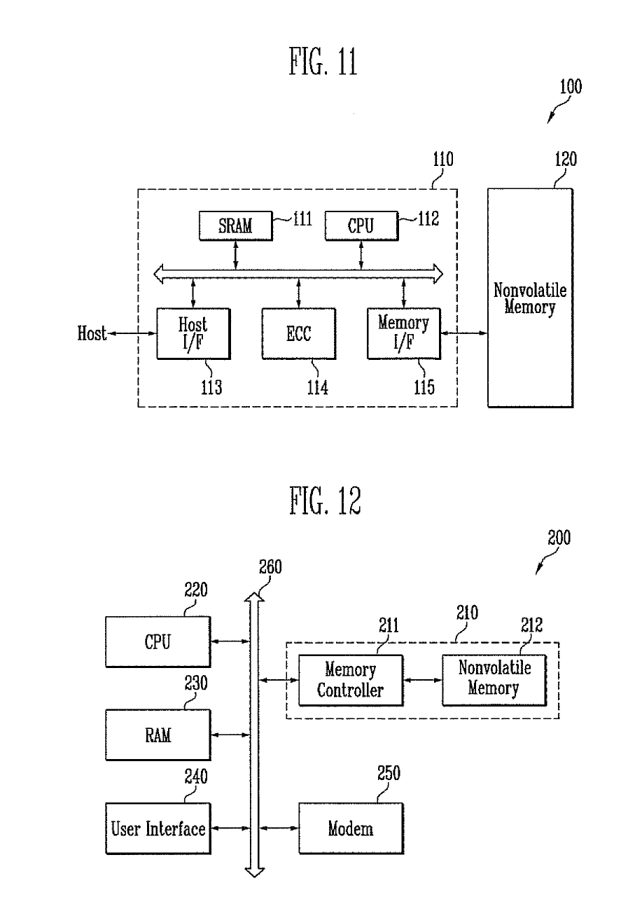

FIG. 12 shows the construction of a computing system in accordance with an embodiment of this disclosure.

As shown in FIG. 12, the computing system 200 according to the embodiment may include a CPU 220, RAM 230, a user interface 240, a modem 250, and a memory system 210, which are electrically coupled through a system bus 260. If the computing system 200 is a mobile device, the computing system 200 may further include a battery for supplying operating voltages to the computing system 200. The computing system 200 may further include an application chipset, a camera image processor (CIS), a mobile DRAM, and so on.

The memory system 210 may include a non-volatile memory device 212 and a memory controller 211, such as those described with reference to shown in FIG. 11.

According to the present invention, Holes are formed by etching a target etch layer using the first and the second mask patterns as an etch barrier. Thus, it is possible to form holes in condition that an interval between the holes in the first direction is different from an interval between the holes in the second direction, and the holes may have sections in which first and second widths are substantially the same.

What is claimed is:

1. A method of manufacturing a semiconductor device, the method comprising:
forming a target etch layer;
forming a first mask pattern on the target etch layer, wherein the first mask pattern includes line patterns extended in parallel in a first direction;
forming a second mask pattern configured to comprise openings at positions where the openings overlap with spaces between the line patterns, before or after forming the first mask pattern, wherein each of the openings has a hole form and a first interval between the adjacent openings in the first direction is shorter than a second interval between the adjacent openings in a second direction that crosses the first direction; and
forming holes by etching the target etch layer using the first mask pattern and the second mask pattern as a barrier.

2. The method of claim 1, wherein in each opening of the second mask pattern, a second width in the second direction is greater than a first width in the first direction.

3. The method of claim 2, wherein each of the holes has a polygonal section at least one surface of which is a curved surface.

4. The method of claim 2, wherein each of a width of the line pattern and a space width between the lines patterns in the first mask pattern is substantially identical with the first width.

5. The method of claim 4, wherein the spaces between the line patterns are alternately exposed through the openings arranged in the second direction.

6. The method of claim 2, wherein:
a width of the line pattern is greater than the second interval, and
a space width between the lines patterns is substantially identical with the first width.

7. The method of claim 1, wherein forming the second mask pattern comprises:
forming a hard mask layer;
forming photoresist patterns of a positive type on the hard mask layer; and
forming the second mask pattern by etching the hard mask layer using the photoresist patterns as a barrier.

8. The method of claim 1, wherein forming the target etch layer comprises alternately forming first material layers and second material layers.

9. The method of claim 8, further comprising forming vertical channel layers in the holes.

10. The method of claim 8, further comprising forming vertical electrode layers in the holes.

11. A semiconductor device, comprising:
vertical pillars arranged in a matrix of a first direction and a second direction that crosses the first direction, wherein a first interval between the adjacent vertical pillars in the first direction is shorter than a second interval between the adjacent vertical pillars in the second direction; and
interlayer insulating layers and conductive layers stacked alternately and configured to surround the vertical pillars,
wherein each vertical pillar has a polygonal section at least one surface of which is a curved surface.

12. The semiconductor device of claim 11, wherein:
the vertical pillar has a rectangle pillar form including one side and the opposite side, which are flat surfaces, and the other side and the opposite side which are curved surfaces.

13. The semiconductor device of claim 11, further comprising a memory layer configured to surround the vertical pillars, wherein the vertical pillars are used as vertical channel layers.

14. The semiconductor device of claim 13, further comprising:
a pipe gate formed under the interlayer insulating layers and the conductive layers alternately stacked; and
pipe channels formed in the pipe gate and each configured to couple one or more pairs of the vertical pillars.

15. The semiconductor device of claim 11, further comprising a memory layer configured to surround the vertical pillars, wherein the vertical pillars are used as vertical electrode layer.

16. The semiconductor device of claim 11, further comprising a pattern layer formed over the interlayer insulating layers and the conductive layers alternately stacked and configured to comprise openings that penetrated by the vertical pillars.

17. The semiconductor device of claim 11, further comprising:
a first pattern layer formed over the interlayer insulating layers and the conductive layers alternately stacked and extended in parallel in the first direction, wherein the first pattern layer configured to have spaces between the line patterns penetrated by the vertical pillars.

18. The semiconductor device of claim 11, further comprising:
a second pattern layer formed over the interlayer insulating layers and the conductive layers alternately stacked and configured to have openings penetrated by the vertical pillars, wherein a first interval between the adjacent openings in the first direction is shorter than a second interval between the adjacent openings in the second direction.

19. The semiconductor device of claim 11, further comprising:
a first pattern layer formed over the interlayer insulating layers and the conductive layers alternately stacked and configured to include line patterns extended in parallel in the first direction, wherein the vertical pillars penetrate spaces between the line patterns; and
a second pattern layer formed over the first pattern layer in such a way as to fill spaces between the line patterns, configured to comprise openings that penetrated by the vertical pillars, and configured to have a first interval between the adjacent openings in the first direction shorter than a second interval between the adjacent openings in the second direction.

20. The semiconductor device of claim 11, further comprising:
a first pattern layer formed over the interlayer insulating layers and the conductive layers alternately stacked and configured to comprise line patterns extended in parallel in the first direction, wherein the vertical pillars penetrate spaces between the line patterns; and
a second pattern layer formed under the first pattern layer, configured to comprise openings that penetrated by the vertical pillars, and configured to have a first interval between the adjacent openings in the first direction shorter than a second interval between the adjacent openings in the second direction.
